(19) United States
(12) Patent Application Publication
(10) Pub. No.: US 2007/0274434 A1
(43) Pub. Date: Nov. 29, 2007

(54) Period-to-Digital Converter

(76) Inventors: Evangelos Arkas, London (GB); Nicholas Arkas, London (GB)

Correspondence Address: SEYFARTH SHAW LLP, 131 S. DEARBORN ST., SUITE2400, CHICAGO, IL, 60603-5803, US

(21) Appl. No.: 10/543,422

(22) PCT Filed: Jan. 27, 2004
(86) PCT No.: PCT/GB04/00341

§ 371 Date: Jun. 14, 2007

(30) Foreign Application Priority Data
Jan. 27, 2003 (GB) 0301840.5

(51) Int. Cl. H03K 25/00

(52) U.S. Cl. 377/94

(57) ABSTRACT

A period-to-digital converter includes a clock (1) for generating a timing signal, delay lines (2) for producing cumulatively incrementally delayed timing signals for each cycle of the timing signal and an isolator (3) connected in parallel to the delay lines for generating a signal indicative of a number of partial cycles of timing signal corresponding to which to the incrementally delayed turning signals last contained a specific feature. First and second counters (5, 8) connected to the isolator are enabled for successive time periods to be measured and the first and second latches (11, 12) respectively connected to the first and second counters are latched at the end of alternate successive time periods respectively. An arithmetic module (22) connected to the first and second latches obtains difference values between their output values, which difference values are representative of the successive time periods respectively.

This invention relates to a period-to-digital converter.

The production of high-resolution clock circuits using incremental delay lines is known. For example, U.S. Pat. No. 5,903,176-A discloses a circuit using eight incremental delay lines and a shift register for measuring a time interval between the leading edges of two control pulses with a resolution sixteen times that of the clock frequency. U.S. Pat. No. 6,246,737-A discloses an apparatus for measuring intervals between signal edges, using a tapped delay line formed by a series of logic gates. A clock signal and an output signal from each gate form a set of phase distributed periodic timing signals which are applied to a start time measurement unit and a stop time measurement unit. The start and stop time measurement units measure a time period in clock cycles and fractional cycles between an arming signal and a start signal and the arming signal and a stop signal respectively and time period represented by the start output data is subtracted from the time period represented by the stop output data to determine an interval between the start and stop signals in cycles and fractional cycles of the clock signal.

However, neither of these instances of prior art discloses a method of measuring immediately successive time periods in cycles and fractions of cycles of a clock period.

It is an object of the present invention to at least ameliorate the aforesaid disadvantage of the prior art.

According to the present invention there is provided a period-to-digital converter including: clock means for generating a timing signal; delay means connected to the clock means for receiving the timing signal and producing a plurality of cumulatively incrementally delayed timing signals for each cycle of the timing signal; isolator means connected to the delay means for receiving the delayed timing signals, isolating a feature of the incrementally delayed timing signals and outputting a signal indicative of which of the incrementally delayed timing signals last contained the feature, indicative of a number of partial cycles of timing signal received by the isolator means; first counting means connected to the isolator means for selectively counting a first number of cycles and partial cycles of the timing signal received by the isolator means; first latching means connected to the first counting means for latching a first value corresponding to the first number of cycles and partial cycles received from the first counting means and outputting a first output value representative thereof; second counting means connected to the isolator means for selectively counting a second number of cycles and partial cycles of the timing signal received by the isolator means; second latching means connected to the second counting means for latching a second value corresponding to the second number of cycles and partial cycles received from the second counting means and outputting a second output value representative thereof; enabling means for selectively enabling the first counting means and the second counting means for successive time periods to be measured and for selectively latching the first and second latching means at the end of alternate successive time periods respectively; arithmetic means connected to the first latching means and the second latching means for obtaining the difference between the first output value and the second output value to output difference values representative of the successive time periods respectively.

Conveniently, the delay means comprises a plurality of delay lines in parallel.

Preferably, an incremental delay introduced by each delay line is a product of a reciprocal of a sum of the plurality of delay lines and a period of the clock source.

Advantageously, the isolator means comprises means to isolate a leading pulse edge of the incrementally delayed timing signals.

Preferably, the first counting means comprises a first counter for counting whole cycles of the timing signal and a first priority encoder for counting partial cycles of the timing signal.

Preferably, the second counting means comprises a second counter for counting whole cycles of the timing signal and a second priority encoder for counting partial cycles of the timing signal.

Conveniently, the switching means comprises flip-flop means.

Advantageously, the arithmetic means comprises multiplexer/subtractor means and multiplexer means.

Alternatively, the arithmetic means comprises first multiplexer means and second multiplexer means both having outputs to an arithmetic/logic unit.

The invention will now be described, by way of example, with reference to the accompanying drawings, in which:

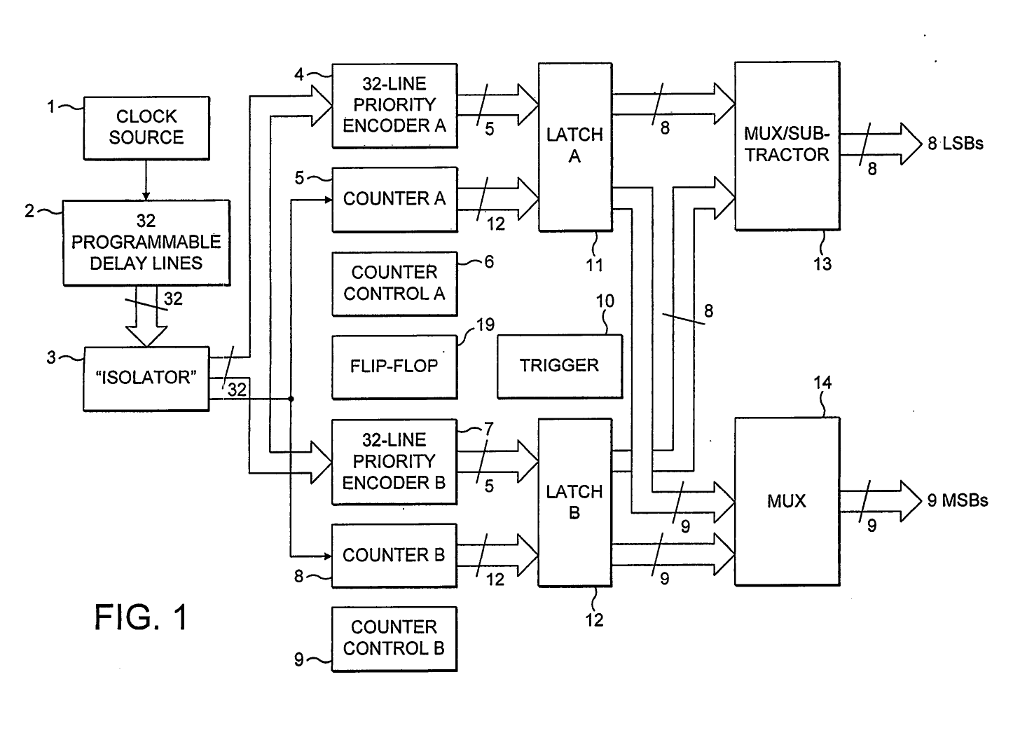

FIG. 1 is a block diagram of a period-to-digital converter according to the invention, showing data flow connections;

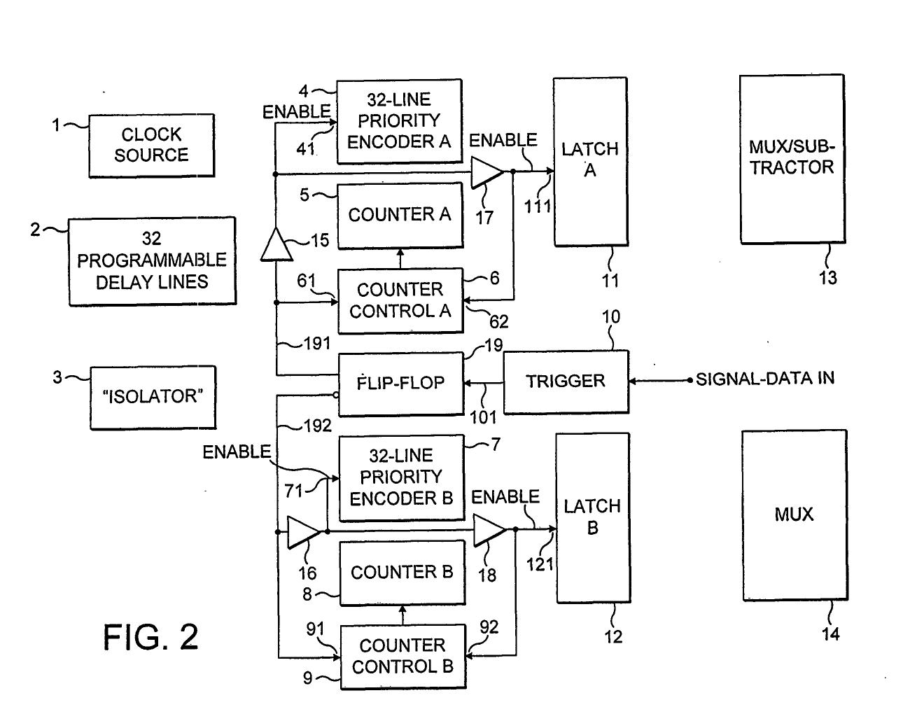

FIG. 2 is a block diagram of the period-to-digital converter of FIG. 1, showing control connections;

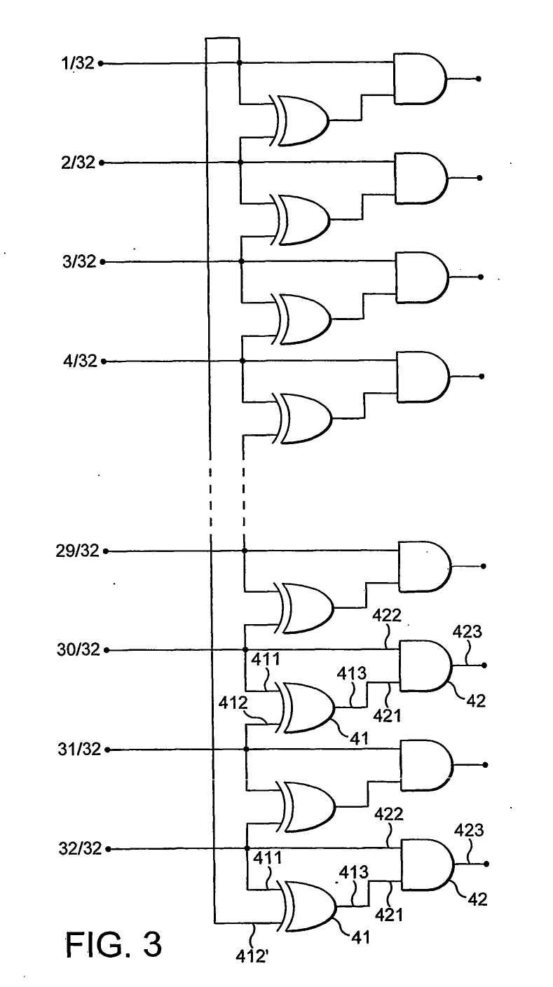

FIG. 3 is a schematic diagram of the isolator of the period-to-digital converter of FIGS. 1 and 2; and

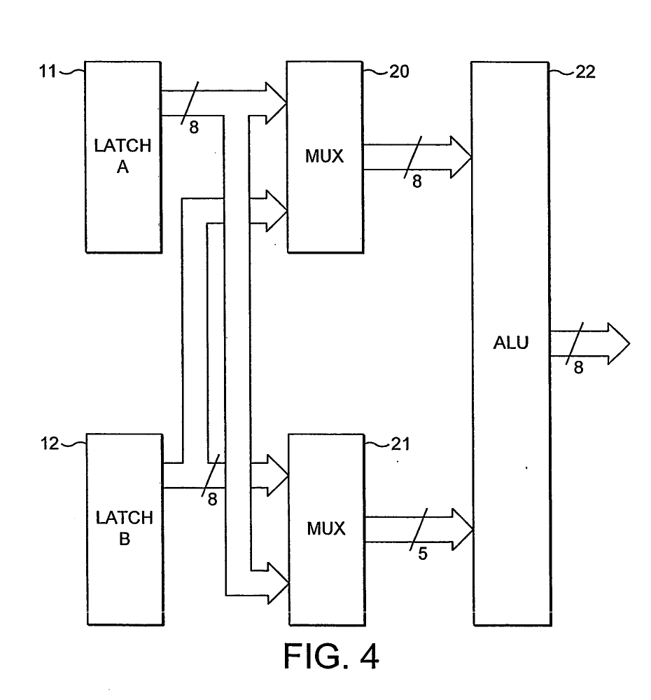

FIG. 4 is a block diagram of the multiplexer/subtractor 13 of the period-to-digital converter of FIGS. 1 and 2.

In the figures, like reference numerals represent like parts.

Referring to FIG. 1, a clock source 1 is connected in parallel to 32 programmable delay lines 2. The clock source may be a crystal oscillator or multivibrator or any other high-accuracy periodic oscillator. The delay P_{DELAY}(n) of the nth of the 32 delay lines is given by the formula:

$${P}_{DELAY} ( n ) = \frac{{P}_{CLK}}{{N}_{DELAY}} ⨯ n for n = 0 , … , {N}_{DELAY} - 1$$

where P_{CLK} is the period of the clock source 1 and N_{DELAY} is the number of delay lines. Although 32 delay lines are described in the present example, it will be understood that a different number of delay lines may be used dependant on the number of partial cycles of the clock source to be used to measure a time interval. Moreover, although parallel delay lines are described, it will be understood that other arrangements of producing incremental delays, such as a tapped delay line, may be used.

Outputs of the 32 delay lines 2 are connected in parallel to an isolator 3, a schematic diagram of which is shown in FIG. 3. The isolator circuit 3 comprises a bank of 32 EXOR gates 41 connected in parallel to each other and a bank of 32 AND gates 42 in parallel to each other. A first input 411 of each EXOR gate is connected to an output of a corresponding delay line of the series of 32 delay lines and a second input 412 of each EXOR gate is connected to an output of a next successive adjacent one of the series of 32 delay lines, except that the second input 412′ of the 32^{nd} EXOR is connected to an output of the 1^{st} of the series of 32 delay lines. A first input 421 of each of the AND gates 42 is connected to an output 413 of a corresponding EXOR gate and a second input 422 of each AND gate 42 is connected to the output of the corresponding delay line. Each of the AND gates 42 has an output 423.

32-bit output from the isolator 3 is connected in parallel to an input of a first 32-line priority encoder 4 and a second 32-line priority encoder 7. A one-bit output from the isolator 3 is connected in parallel to a first counter 5 and a second counter 8.

A five-bit output from the first 32-line priority encoder 4 and a 12-bit output from the first counter 5 are connected to respective inputs of a first latch 11. A five-bit output from the second 32-line priority encoder 7 and a 12-bit output from the second counter 8 are connected to respective inputs of a second latch 12.

An 8-bit first output from the first latch 11 is connected to a first input of a multiplexer/subtractor 13 and a 9-bit second output of the first latch 11 is connected a first input of a multiplexer 14. An 8-bit first output from the second latch 12 is connected to a second input of the multiplexer/subtractor 13 and a 9-bit second output from the second latch 12 is connected to a second input of the multiplexer 14. There is a 8-bit least significant bits (LSB) digital output from the multiplexer/subtractor 13 and a 9-bit most significant bits (MSB) digital output from the multiplexer 14. The combined output therefore forms a 17-bit member.

FIG. 4 is a block diagram of the multiplexer/subtractor 13 shown in FIGS. 1 and 2. This unit is required to subtract the initial asynchronous/erroneous measurement from subsequent measurements. An 8-bit output from the first latch 11 is connected in parallel to a first input of a first multiplexer 20 and a second input of a second multiplexer 21 and an 8-bit output from the second latch 12 is connected in parallel to a second input of the first multiplexer 20 and a first input of the second multiplexer 21. There are 8-bit digital outputs from the first multiplexer 20 and the second multiplexer 21 respectively to an arithmetic/logic unit 22, and an 8-bit digital output of the period-to-digital converter from the arithmetic/logic unit.

The latches, multiplexers and the arithmetic/logic unit are all 9-bit devices, some with carry on outputs. The carry on output can also be used as the 9-bit.

Control lines for controlling the above components are illustrated in FIG. 2. A trigger 10, for signalling a time interval to be measured, has a signal-data input and is connected by a trigger control line 101 to a flip-flop 19 such that the flip-flop 19 changes state every time the flip-flop receives a pulse from the trigger 10. The trigger 10 may comprise the detection of a zero crossing, or of a peak or trough detection as described in GB 2379027-A. It is the signal/data for digitisation itself that provides the required zero-crossings and/or the peaks and troughs to activate the trigger. A first output of the flip-flop 19 is connected by a first flip-flop control line 191 to a starting/stopping input 61 of a counter control module 6 for starting the first counter 5, to an enable input 41 of the first 32-line priority encoder 4, to an enable input 111 of the first latch 11 and to a reset input 62 of the first counter control module 6. Similarly a second output of the flip-flop 19 is connected by a second flip-flop control line 192 to a starting/stopping input 91 of a second counter control module 9 for staring the second counter 8, to an enable input 71 of the second 32-line priority encoder 7, to an enable input 121 of the second latch 12 and to a reset input 92 of the second counter control module 9. In order for the flip-flop 19 to start the first counter 5 substantially simultaneously with enabling the first 32-line priority encoder 4, a first priority encoder buffer delay 15 is interposed on the first flip-flop control line 191 between the starting/stopping input 61 of the first counter control module 6 and the enable input 41 of the first 32-line priority encoder 4. In addition, a first latching buffer delay 17 is interposed on the first flip-flop control line 191 between the first priority encoder buffer delay 15 and the enable input 111 of the first latch 11 and the resetting input 62 of the first counter control module 6, to allow values from the first 32-line priority encoder 4 and the first counter 5 to be latched by the first latch 11 before the latch is dis-enabled and the first counter 5 is re-set in a manner to be described. A corresponding second priority encoder buffer delay 16 and second latching buffer delay 18 are provided in corresponding positions on the second flip-flop control line 192 from the second output of the flip-flop 19.

For the sake of clarity of the drawings, FIG. 2 does not show control connections to the multiplexer/subtractor 13 or the multiplexer 14, however they may be connected to, and controlled by, the flip-flop 19 or any other suitable method of control may be used.

In use the period-to-digital converter is capable of performing measurements of successive periods of time and outputting digital signals representative of those periods of time.

A timing signal is supplied from the clock source 1 in parallel to the inputs of the series of 32 incremental parallel delay lines 2. The series of 32 programmable delay lines are programmed such that successive delay lines in the series delay the timing signal by an incremental 1/32 of the period of the clock source compared with a delay imposed by an immediately preceding delay line in the series. Thus the first delay line imposes no delay on the timing signal, the second delay line delays the timing signal by 1/32 of the clock cycle and the last, i.e. 32^{nd}, delay line delays the timing signal by 31/32 of the clock cycle. The delayed outputs are presented in parallel to the isolator 3 in an asynchronous flow-through manner to detect the “wave front” of the timing signal through the delay lines. The isolator 3 locates and isolates a latest appearance of a leading pulse edge of the incrementally delayed timing signals.

Although the isolator is described as detecting a leading edge of a pulse, it will be apparent that the isolator may alternatively be designed to detect, for example, a trailing edge of a pulse, or a peak or trough of, for example, a sinusoidal or ramp signal.

The operation of the isolator may be described as follows. Consider, for the sake of simplicity, an isolator operating on the output from only eight programmable incremental delay lines. Before the clock source 1 is active, the output of the eight programmable delay lines is:
00000000

with the outputs number, left to right, 0 to 7. When the clock source 1 becomes active, the output of the delay lines will have the following states shown in the first block of figures in each subsequent ⅛ of a clock cycle:

| | | | | | | | | | | | | | | | | |
|---|---|---|---|---|---|---|---|---|---|---|---|---|---|---|---|---|
| 0 | 0 | 0 | 0 | 0 | 0 | 0 | 0 | 0 | | | | | | | | |
| 1/8 | 1 | 0 | 0 | 0 | 0 | 0 | 0 | 0 | 1 | 0 | 0 | 0 | 0 | 0 | 0 | 0 |
| 2/8 | 1 | 1 | 0 | 0 | 0 | 0 | 0 | 0 | 0 | 1 | 0 | 0 | 0 | 0 | 0 | 0 |
| 3/8 | 1 | 1 | 1 | 0 | 0 | 0 | 0 | 0 | 0 | 0 | 1 | 0 | 0 | 0 | 0 | 0 |
| 4/8 | 1 | 1 | 1 | 1 | 0 | 0 | 0 | 0 | 0 | 0 | 0 | 1 | 0 | 0 | 0 | 0 |
| 5/8 | 0 | 1 | 1 | 1 | 1 | 0 | 0 | 0 | 0 | 0 | 0 | 0 | 1 | 0 | 0 | 0 |
| 6/8 | 0 | 0 | 1 | 1 | 1 | 1 | 0 | 0 | 0 | 0 | 0 | 0 | 0 | 1 | 0 | 0 |
| 7/8 | 0 | 0 | 0 | 1 | 1 | 1 | 1 | 0 | 0 | 0 | 0 | 0 | 0 | 0 | 1 | 0 |
| 8/8 | 0 | 0 | 0 | 0 | 1 | 1 | 1 | 1 | 0 | 0 | 0 | 0 | 0 | 0 | 0 | 1 |
| 9/8 | 1 | 0 | 0 | 0 | 0 | 0 | 0 | 0 | 1 | 0 | 0 | 0 | 0 | 0 | 0 | 0 |
| 10/8 | 1 | 1 | 0 | 0 | 0 | 0 | 0 | 0 | 0 | 1 | 0 | 0 | 0 | 0 | 0 | 0 |
| 11/8 | 1 | 1 | 1 | 0 | 0 | 0 | 0 | 0 | 0 | 0 | 1 | 0 | 0 | 0 | 0 | 0 |
| 12/8 | 1 | 1 | 1 | 1 | 0 | 0 | 0 | 0 | 0 | 0 | 0 | 1 | 0 | 0 | 0 | 0 |

The underlined 0 and 1 in each column indicate the position of the leading edge of the delayed timing signal for each of the incremental delay lines respectively. The second block of figures shows the corresponding 8-bit output of the isolator 3. That is, a ‘1’ is output from the isolator whenever a leading edge of a delayed clock pulse is received at the output of the corresponding delay line.

The output from the isolator 3 is presented, in the case of 32 delay lines, as a 32-bit number, to the first or second priority encoder 4,7. The selected priority encoder outputs the position of the most significant bit, i.e. the only ‘1’ in the number, as a 5-bit binary number, a 5-bit binary number being sufficient to represent the 32 possible positions of the ‘1’.

In the example cited in the text, output 7 of the programmable delay lines will be in state 1 for 4 consecutive ‘delays’. The line priority encoder will give priority to output 7 and therefore output a value that does not match the actual leading edge of the clock signal. During that time it will have travelled through outputs 0, 1 and 2.

What the isolator does is filter out everything except the leading edge so that the line priority encoder will output a value that correctly matches the leading edge of the clock signal.

Since, in general, a time period to be measured may be greater than a single period of the clock source, it is necessary to measure complete cycles of the clock source as well as the fractional cycles described above.

For this reason, the first counter 5 and the second counter 8 have respective Clock In ports connected to one of, preferable the last, output of the isolator 3. When performing a measurement the leading edge of the timing signal will in general cycle many times and the first and second counters 5,8 count the number of times this occurs. As illustrated, the first and second counters are binary asynchronous 12-bit counters running at the same frequency as the clock source 1, but other counters may be used.

When counting successive time periods, alternate periods are measured by the first counter 5 and first priority encoder 4 and by the second counter 8 and second priority encoder 7. Consider a state when a first count representing the end of an immediately previous time period is latched in the second latch 12 and the first counter 5 and first priority encoder 4 are measuring a succeeding current time period. When the trigger 10 receives an input signal at the signal—data input and transmits a pulse to indicate the end of the current time period to be measured and the beginning of the next time period, the flip-flop 19 changes state and the inputs of the first 32-line priority encoder 4 are disabled and the instantaneous position of the ‘1’ in the isolator output at that time is transformed by the first priority encoder 4 into a 5-bit binary number representing the position of the most significant bit, i.e. the ‘1’. This 5-bit binary number is output to the first latch 11. The change of state of flip-flop 19 signalled to the first counter control module 6 also simultaneously stops the first counter 5 counting and the value counted by the first counter in the current time period is also output by the first counter 5 to the first latch 11 and the first counter 5 reset to zero. The value of the current measurement in the first latch 11 and the value of the previous measurement in the second latch 12 are both output to the multiplexer/subtractor 13. The multiplexer/subtractor 13 subtracts the five least significant bits of the previous reading, representing the fractional number of cycles at the beginning of the current time period, from the value of the present reading from the first latch 11 to determine the number of cycles and fractional cycles of the current time period.

Substantially simultaneously with disenabling the first priority encoder 4 and stopping the first counter 5, the change of state of the flip-flop, signalled over the second flip-flop control line 192, enables the second priority encoder 7 and starts the second counter 8, in order to measure the next successive time period, by subtracting the value latched in the first latch 11 from the value to be latched in the second latch 12 at the end of the next successive time period.

As shown in FIG. 4, the values from the first and second latches 11,12 are selectively switchably output to the first multiplexer 20 and the second multiplexer 21 and the subtraction of one value from the other is performed in the arithmetic/logic unit 22 connected to outputs of the first and second multiplexers 20,21. That is, the first multiplexer 20 and the second multiplexer 21 are configured such that the operation performed by the arithmetic/logic unit 22 is to subtract the five least significant bits of the value from the second latch 12, representing fractional clock cycles, from the eight least significant bits, representing whole and fractional clock cycles, of the value from the first latch 11 and the following operation is to subtract the five least significant bits of the value from the first latch 11 from the eight least significant bits of the value from the second latch 12, and so on alternately. It will be understood that some number other than eight least significant bits may be used, but eight are conventionally used as many known devices operate with 8 bits.

Because the trigger 10 is not synchronised with the clock source 1, the first measurement made with the digital-to-period converter after switching on the clock source is not accurate, however for subsequent measurements, since only the difference between the five least significant bits of the reading at the beginning and end of a time period to be measured is used, the error in the number of fractional parts of a clock cycle is eliminated thereby, for the subsequent measurements. This is why the multiplexer/substractor 13 is required.

Details of the means of synchronisation of switching between the counters 5,8, priority encoders 4,7 and latches 11,12 are best appreciated by reference to FIG. 2. As described above, flip-flop 19 changes state every time the flip-flop 19 receives a pulse from trigger 10, in response to an input at the signal—data input, to indicate the end of one time period and the beginning of a succeeding time period to be measured. Delay buffers 15,16,17,18 are included in the control circuits 191,192 to ensure that switching operations are performed in the correct sequence. Consider first, for simplicity, changes in the first counter 5 and first priority encoder 4 using control circuit 191. When the state of flip-flop 19 changes, an OFF-signal may be signalled to the first counter control module 6, which stops the first counter 5 from counting. There is a delay associated with stopping the first counter 5 and a delay inserted by the first priority encoder buffer delay 15 is chosen such that the OFF-signal disables the first priority encoder 4 at the same time as the first counter 5 stops counting. A subsequent further delay introduced by the first latching buffer delay 17 is chosen to provide sufficient time for the first priority encoder 4 to present an instantaneous value of a binary number, corresponding to the isolator output, to the first latch 11 before the OFF-signal causes the first latch 11 to latch. The twice delayed OFF-signal pulse from the first latching buffer delay 17 is also input to the reset input 62 of the first counter control module 6 to reset the first counter 5.

At substantially the same time, the change in state of the flip-flop 19 sends an ON-signal, over the second flip-flop control line 192, to the second counter control module 9 to start the second counter 8, and the ON-signal from the flip-flop 19 is delayed by the second priority encoder buffer 16 so that the second priority encoder 7 is enabled at the same time as the second counter 8 starts counting. The unlatching of the second latch 12 by the ON-signal is delayed by the second latching buffer 18. The ON-signal has no effect on the second control module 9.

Thus the period-to-digital converter provides an apparatus for measuring successive time intervals with greater precision than the period of the clock source used. The effective frequency of the period-to-digital converter is the product of the frequency of the clock source and the number of incremental delays used. Therefore, in the embodiment described, the resolution of the clock is increased by a factor of 32.

1. A period-to-digital converter including: clock means for generating a timing signal; delay connected to the clock means for receiving the timing signal and producing a plurality of cumulatively incrementally delayed timing signals for each cycle of the timing signal; isolator connected to the delay means for receiving the delayed timing signals, isolating a feature of the incrementally delayed timing signals and outputting a signal indicative of which of the incrementally delayed timing signals last contained the feature, indicative of a number of partial cycles of timing signal received by the isolator means; first counting connected to the isolator means for selectively counting a first number of cycles and partial cycles of the timing signal received by the isolator means; first latching connected to the first counting means for latching a first value corresponding to the first number of cycles and partial cycles received from the first counting means and outputting a first output value representative thereof; second counting connected to the isolator means for selectively counting a second number of cycles and partial cycles of the timing signal received by the isolator means; second latching connected to the second counting means for latching a second value corresponding to the second number of cycles and partial cycles received from the second counting and outputting a second output value representative thereof; enabling for selectively enabling the first counting means and the second counting means for successive time periods to be measured and for selectively latching the first and second latching means at the end of alternate successive time periods respectively; arithmetic connected to the first latching means and the second latching means for obtaining the difference between the first output value and the second output value to output difference values representative of the successive time periods respectively.

2. A period-to-digital converter as claimed in claim 1, wherein the delay comprises a plurality of delay lines in parallel.

3. A period-to-digital converter as claimed in claim 2, wherein an incremental delay introduced by each delay line is a product of a reciprocal of a sum of the plurality of delay lines and a period of the clock.

4. A period-to-digital converter as claimed in claim 1 wherein the isolator comprises means to isolate a leading pulse edge of the incrementally delayed timing signals.

5. A period-to-digital converter as claimed in claim 1, wherein the first counting means comprises a first for counting whole cycles of the timing signal and a first priority for counting partial cycles of the timing signal.

6. A period-to-digital converter as claimed in claim 1, wherein the second counting means comprises a second for counting whole cycles of the timing signal and a second priority for counting partial cycles of the timing signal.

7. A period-to-digital converter as claimed in claim 1, wherein the switching means comprises flip-flop.

8. A period-to-digital converter as claimed in claim 1, wherein the arithmetic means comprises multiplexer/subtractor and multiplexer.

9. A period-to-digital converter as claimed in claim 1, wherein the arithmetic means comprises first multiplexer and second multiplexer both having outputs to an arithmetic/logic.
